(19) United States
(12) Patent Application Publication
(10) Pub. No.: US 2006/0148243 A1
(43) Pub. Date: Jul. 6, 2006

(54) METHOD FOR FABRICATING A DUAL DAMASCENE AND POLYMER REMOVAL

(76) Inventor: Jeng-Ho Wang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/905,359

(22) Filed: Dec. 30, 2004

(51) Int. Cl. H01L 21/4763

(52) U.S. Cl. 438/638

(57) ABSTRACT

A method for fabricating a dual damascene includes a partial etching process, a photoresist layer stripping process, and a blanket etching process. After the blanket etching process, an in-situ dry cleaning process is performed to remove residual polymers resulting from the etching processes.

### BACKGROUND OF INVENTION

1. Field of the Invention

The invention relates to a method for fabricating a dual damascene, and more particularly, to a method for fabricating a dual damascene that can effectively remove residual polymers resulting from etching processes.

2. Description of the Prior Art

To meet the needs of high integration and high processing speed in 0.13 micron generation integrated circuits (ICs), a copper (Cu) interconnect technology has now become an effective solution. Cu is approximately 30% lower in resistivity than Al and has fewer reliability concerns such as electromigration. Cu interconnect technology, by and large, has been implemented employing damascene techniques, wherein an ILD, such as a silicon oxide layer, e.g., derived from tetraethyl orthosilicate (TEOS) or silane, or a low-k material, is formed over an underlying metal level containing metal features, e.g., Cu or Cu alloy features with a silicon nitride capping layer. A damascene opening, e.g., via hole, trench, or dual damascene opening, is then formed in the ILD. A barrier layer and optional seed layer are then deposited, followed by Cu deposition, as by electro-deposition or electroless deposition. Low-k materials for the ILD comprises fluorinated silica glass (FSG), organosilicate (OSG), and ultra low-k (ULK) materials (k<2.5).

The process of fabricating a dual damascene includes a trench-first dual damascene process and a via-first dual damascene process. Please refer to FIGS. 1-5, which are schematic diagrams of the prior art method of a trench-first dual damascene process. As shown in FIG. 1, a substrate 12 is provided, wherein the substrate 12 has a conductive layer 14 thereon and a bottom layer 16 over the conductive layer 14. Then, a first dielectric layer 18, an etch-stop layer 20, a second dielectric layer 21, and an anti-reflective coating (ARC) layer 22 are formed sequentially over the bottom layer 16. Generally, the etch-stop layer 20 is formed with silicon nitride (SiN). After forming the ARC layer 22, a spin-coating process is performed to form a first photoresist layer 24 on the ARC layer 22, and a lithography process is also performed to define a trench opening 26 of a conductive line pattern in the first photoresist layer 24.

Please refer to FIG. 2. A first etching process is performed to etch the ARC layer 22 and the second dielectric layer 21 through the trench opening 26 of the first photoresist layer 24 so that a trench 28 is formed in the second dielectric layer 21. The etching stops on the etch-stop layer 20. Then, the first photoresist layer 24 and the ARC layer 22 are stripped. As shown in FIG. 3, a planarization layer 30 is formed over the second dielectric layer 21; meanwhile, the trench recess 28 is filled with the planarization layer 30. A second photoresist layer 32 is then formed over the planarization layer 30. Then, another photolithography process is performed to define a via opening 34 on the second photoresist layer 32.

As shown in FIG. 4, a second etching process is performed, taking the second photoresist layer 32 as an etching mask, to etch the planarization layer 30, the second etch-stop layer 20, and the first dielectric layer 18 to the bottom layer 16 through the via opening 34 so that a via hole 36 is formed. Referring to FIG. 5, the residual second photoresist layer 32 and the planarization layer 30 is stripped. The bottom layer 16 is then etched to finish the formation of the dual damascene 38 with a trench and a via hole.

However, there is a serious problem that undesired polymers 40 forming on the surface of the sidewall and bottom of the dual damascene 38 are produced during the above-described etching processes. Accordingly, if a metal conductive layer 42 is directly filled in the dual damascene 38 to form a metal conductive line and a via plug, the resistance will increase. According to the prior art, a solution for the residual polymer problem is to move the substrate 12 into a wet cleaning chamber to perform a wet cleaning process. In fact, wet cleaning processes have been used in the past to remove polymers formed on oxide type dielectric sidewalls. However, the recent introduction of low-k materials, such as OSG, in combination with silicon carbide (SiC) etch-stop materials and copper fill materials has rendered previous cleaning processes ineffective in removing polymers from OSG and other low-k dielectric sidewalls. For example, polymers may comprise carbon-fluorine (C—F) bonds that are hardly removed through conventional wet cleaning processes.

For the via-first dual damascene process, it includes defining a via pattern by a first photoresist layer, etching the first and second dielectric layer underlying the first photoresist layer to expose the bottom conductive layer through the via pattern, removing the first photoresist layer, forming a second photoresist layer with a trench pattern, and etching the first dielectric layer to form a trench by taking a SiC layer or a SiN layer between the first and second dielectric layer as an etch-stop layer. During the via-first dual damascene process, polymers are also formed on the sidewall and bottom of the dual damascene, which result in device defects such as increased resistance and RC delays. Similarly, a conventional wet cleaning process has trouble to effectively removing the residual polymers caused by etching the dielectric layers formed with low-k materials and SiC etch-stop layer.

In U.S. Pat. No. 6,713,402, entitled “Method for polymer removal following etch-stop layer etch”, an extra process is disclosed in which the substrate is moved to a plasma cleaning chamber for introducing a hydrogen-containing plasma to remove the residual polymers. However, how to remove the residual polymers produced by etching the low-k dielectric layer with a more effective and simpler process without destroying the dual damascene is still an important issue that needs to be considered.

### SUMMARY OF INVENTION

It is therefore a primary objective of the claimed invention to provide a method for fabricating a dual damascene and polymer removal to solve the above-mentioned problem.

According to the claimed invention, the claimed invention method for fabricating a dual damascene comprises providing a substrate having a conductive thereon, sequentially forming a dielectric layer, a hard mask layer, a bottom anti-reflection coating (BARC) layer, and a first photoresist layer on the substrate, wherein the first photoresist layer has a trench opening exposing a portion of the first BARC layer, performing a first etching process to etch the first BARC layer and the underlying hard mask layer through the trench opening to form a trench recess in the hard mask layer, and stripping the first photoresist layer and the first BARC layer. The claimed invention method further comprises sequentially forming a second BARC layer and a second photoresist layer having a via opening exposing a portion of the second BARC layer above the hard mask layer after stripping the first photoresist layer and the BARC layer so that the trench recess is filled with the second BARC layer, performing a second etching process to etch the second BARC layer, the underlying hard mask layer, and the dielectric layer through the via opening to form a via recess in an upper portion of the dielectric layer, stripping the second photoresist layer and the second BARC layer, performing a third etching process to etch the dielectric layer through the via recess and the trench recess until the conductive layer is exposed so as to form a dual damascene, and performing an in-situ dry cleaning process to strip residual polymers resulting from etching the dielectric layer. The in-situ dry cleaning process and the third etching process are performed in a same reaction chamber continuously.

It is an advantage of the claimed invention that the second etching process, the stripping process of the second photoresist layer, the third etching process, and the in-situ dry cleaning process are performed in a same reaction chamber so that the residual polymers formed from the several etching processes can be effectively removed through a simple process and with low cost. The in-situ dry cleaning process includes introducing a cleaning gas, preferably a cleaning gas containing hydrogen (H₂), to the reaction chamber where the etching processes are performed to change the composition of the residual polymers so that the polymers with changed composition can be easily removed.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIGS. 1-5 are schematic diagrams of fabricating a trench-first dual damascene process according to the prior art method.

FIGS. 6-11 are schematic diagrams of fabricating a dual damascene according to the present invention method.

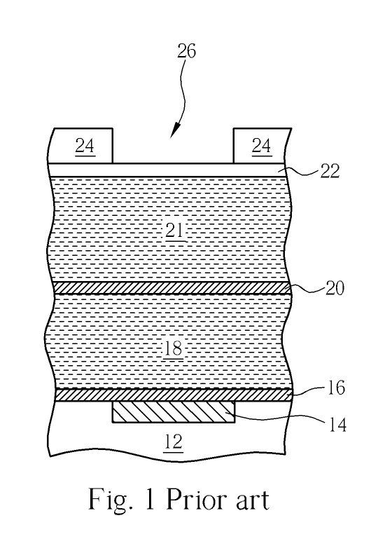

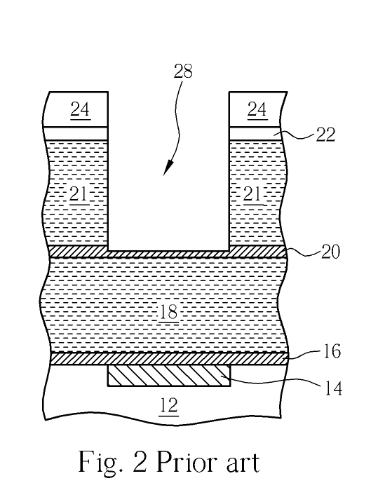

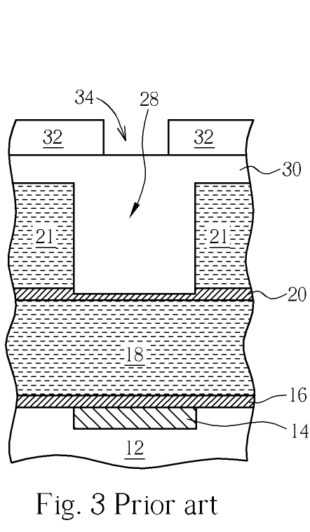

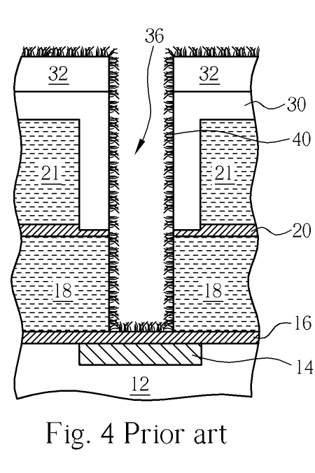

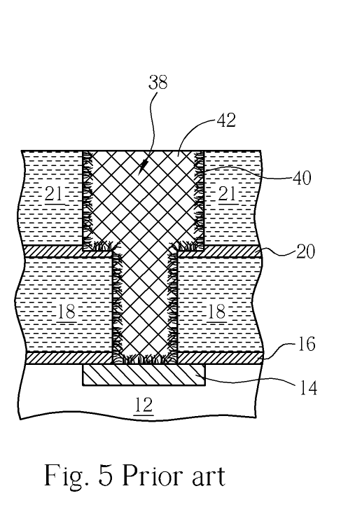

### DETAILED DESCRIPTION

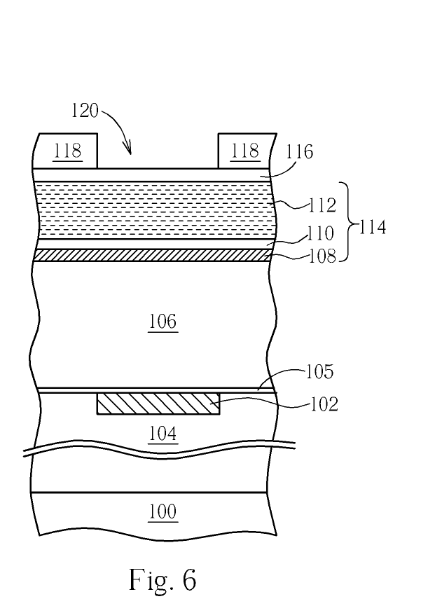

Please refer to FIGS. 6-11. FIGS. 6-11 are schematic diagrams of a trench-first dual damascene process according to the present invention. As shown in FIG. 6, a semiconductor substrate 100 is provided, wherein the semiconductor substrate 100 has a conductive layer 102 thereon and is positioned in a first dielectric layer 104. Then, a bottom layer 105, a second dielectric layer 106, an etch-stop layer 108, a metal layer 110, a mask layer 112, and a first BARC layer 116 are formed over the first dielectric layer 104 and the conductive layer 102. The etch-stop layer 108, metal layer 110, and the mask layer 112 form a composite layer serving as a hard mask 114 during the follow-up etching processes. The etch-stop layer 108 is a SiC layer. The metal layer 110 is preferably a titanium nitride (TiN) layer or a tantalum nitride (TaN) layer. The mask layer 112 is selectively formed with a plasma enhanced oxide (PEOX) layer. In addition, the bottom layer 105 is a SiN layer, and the second dielectric layer 106 is formed with a low-k (k≦2.9) material, such as FSG, OSG, or ULK materials. A first photoresist layer 118 is then deposited above the first BARC layer 116 and a photolithography process is performed to define a trench opening 120 with a conductive line pattern on the first photoresist layer 118.

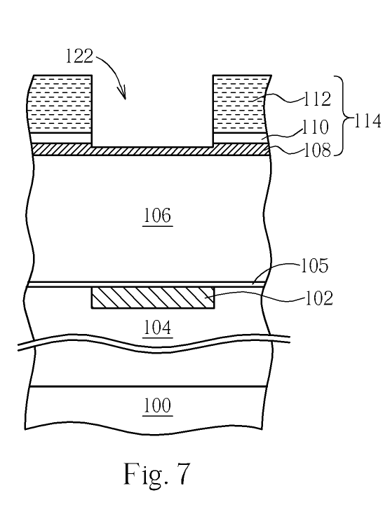

As shown in FIG. 7, a first etching process is then performed to etch the mask layer 112, the metal layer 110 and the etch-stop layer 108 through the trench opening 120 of the first photoresist layer 118 so as to form a trench recess 122. The first etching process is stopped at the etch-stop layer 108. Then, a stripping process is performed to strip the first photoresist layer 118 and the first BARC layer 116.

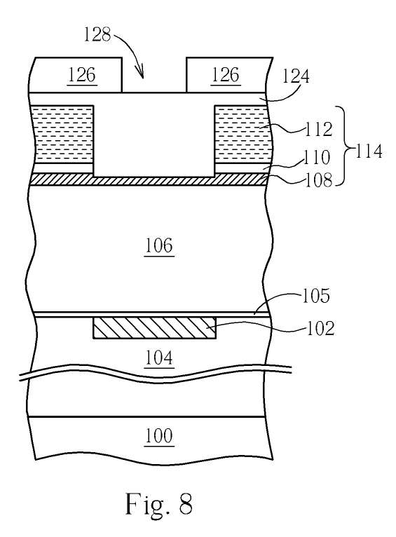

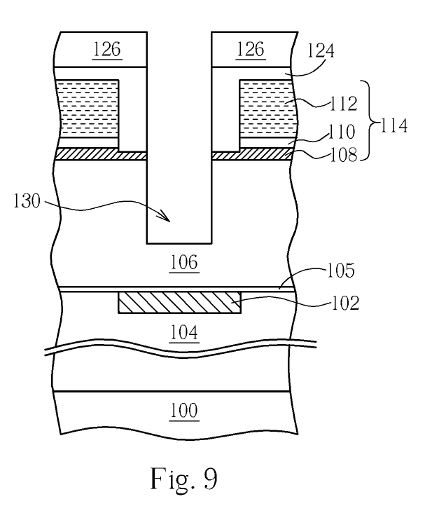

As shown in FIG. 8, a second BARC layer 124 is next formed above the hard mask 114, and the trench recess 122 is filled with the second BARC layer 124. A second photoresist layer 126 is then formed on the second BARC layer 124 and a photolithography process is then performed to define a via opening 128 of a metal interconnect line in the second photoresist layer 126. As shown in FIG. 9, the second photoresist layer 126 is used as an etching mask to perform a second etching process, which is a partial via etching, through the via opening 128 to etch the second BARC layer 124, the etch-stop layer 108, and an upper portion of the second dielectric layer 106. Accordingly, a partial via feature 130 is formed.

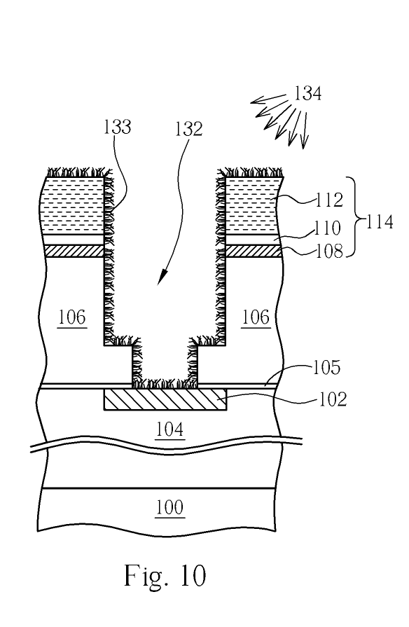

Then, as shown in FIG. 10, oxygen gas is introduced to remove the residual second photoresist layer 126 and the second BARC layer 124. After that, a third etching process, such as a reactive ion etching (RIE) process, is performed through the partial via feature 130 and the trench recess 122 to etch the second dielectric layer 106 and the bottom layer 105 until the conductive layer 102 is exposed. Therefore, a dual damascene 132 with a trench and a via hole is formed in the second dielectric layer 106.

Since the second dielectric layer 106 is formed with low-k materials, those etching processes produce polymers 133 with C—F bonds remaining on the sidewall and the bottom of the dual damascene 132. On the other hand, metal derivatives may also occur while etching the hard mask 114 containing the metal layer 112. Therefore, according to the present invention, an in-situ dry cleaning process 134 is performed to introduce a cleaning gas with hydrogen (H₂), oxygen (O₂), or carbon tetrafluoride (CF₄), preferably hydrogen, into the reaction chamber where the third etching process is performed to strip the residual polymers 133.

During the in-situ dry cleaning process 134, an inert gas, such as argon, or nitrogen is selectively utilized as a carrier of hydrogen to be introduced in the reaction chamber. The cleaning gas provides hydrogen radicals (H*) to replace C—F bonds of polymers 133 with C—H bonds which are removed easily by a following cleaning step. When nitrogen is introduced with hydrogen, it will bombard the polymers 133 to break the C—F bonds and also bombard the hydrogen to increase the concentration of hydrogen radicals so as to raise the performance of the in-situ dry cleaning process.

It should be noted that the second etching process, the step of stripping the second photoresist layer 130 and the second BARC 124, the third etching process, and the in-situ dry cleaning process 134 are preferably performed in the same reaction chamber continuously to effectively remove the residual polymers 133 during the in-situ dry cleaning process 134.

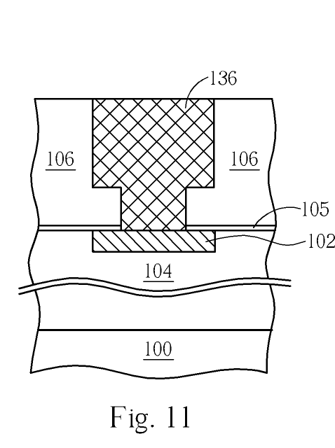

Then, referring to FIG. 11, the semiconductor substrate 100 is selectively moved to a wet cleaning chamber for performing a wet cleaning process on the dual damascene 132. After the wet cleaning process, a conductive layer 136 is filled in the dual damascene 132, wherein the conductive layer 136 can be formed with metal materials, such as copper. A polishing process is then performed to finish the fabrication of the conductive line and via plug.

In another embodiment of the present invention, a via-first dual damascene process comprises etching through the second dielectric layer to form a via hole, forming a trench connecting the via hole in the upper portion of the second dielectric layer with another etching process, and introducing a cleaning gas containing hydrogen, oxygen, or carbon tetrafluoride to perform an in-situ dry cleaning process for stripping residual polymers resulting from etching the second dielectric layer.

To make short of the matter, the present invention method includes performing a partial via etching process, stripping the photoresist layer, performing a blanket etching process, and performing an in-situ dry cleaning process in a same reaction chamber, so that the residual polymers can be removed effectively with a simple process. Therefore, the metal conductive line and via plug have better performance. In contrast to the prior art, the in-situ dry cleaning process of the present invention method is utilized after a multi-step etching process by introducing a cleaning gas containing hydrogen into the reaction chamber where the etching process or stripping process on the photoresist layer are performed. The in-situ dry cleaning process is capable of effectively removing polymers with C—F bonds.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a dual damascene, the method comprising:
providing a substrate having a conductive thereon;
sequentially forming a dielectric layer, a hard mask layer, a first bottom anti-reflection coating (BARC) layer, and a first photoresist layer on the substrate, the first photoresist layer having a trench opening exposing a portion of the first BARC layer;
performing a first etching process to etch the first BARC layer and the underlying hard mask layer through the trench opening to form a trench recess in the hard mask layer;
stripping the first photoresist layer and the first BARC layer;
sequentially forming a second BARC layer and a second photoresist layer on the hard mask layer so that the trench recess is filled with the second BARC layer, the second photoresist layer having a via opening exposing a portion of the second BARC layer;
performing a second etching process to etch the second BARC layer, the underlying hard mask layer, and the dielectric layer through the via opening to form a via recess in an upper portion of the dielectric layer;
stripping the second photoresist layer and the second BARC layer;
performing a third etching process to etch the dielectric layer through the via recess and the trench recess until the conductive layer is exposed so as to form a dual damascene; and
performing an in-situ dry cleaning process to strip residual polymers resulting from etching the dielectric layer, wherein the third etching process and the in-situ dry cleaning process are performed in a same reaction chamber continuously.

2. The method of claim 1, wherein the in-situ dry cleaning process comprises introducing a cleaning gas containing hydrogen (H₂), oxygen (O₂), or carbon tetrafluoride (CF₄).

3. The method of claim 2, wherein the cleaning gas further comprises an inert gas or nitrogen (N₂).

4. The method of claim 3, wherein the inert gas is argon.

5. The method of claim 2, wherein the cleaning gas provides hydrogen radicals for replacing atoms of the residual polymers.

6. The method of claim 1, wherein the hard mask layer is a composite layer comprising a silicon carbide (SiC) layer, a metal layer, and a plasma enhanced oxide (PEOX) layer from bottom to top, and the silicon carbide layer is an etch-stop layer of the first etching process.

7. The method of claim 1, wherein the substrate further comprises a bottom layer positioned above the conductive layer.

8. The method of claim 1, wherein the dielectric layer is formed with low-k materials (k≦2.9).

9. The method of claim 8, wherein the low-k materials comprises organosilicate glass (OSG), fluorinated silica glass (FSG), or ultra low-k (ULK) materials (k<2.5).

10. The method of claim 1, wherein the method further comprises a step of performing a wet cleaning process after the dry cleaning process.

11. The method of claim 1, wherein the second etching process, the process of stripping the second photoresist layer, the third etching process, and the dry cleaning process are performed in the same reaction chamber continuously.

12. A method for polymer removal resulting from forming a via hole, the method comprising:
providing a substrate provided thereon a conductive layer and a low-k (k≦2.9) layer over the conductive layer;
performing an etching process on the low-k layer for forming a via hole so as to expose the conductive layer;
performing an in-situ dry cleaning process to introduce a cleaning gas containing hydrogen (H₂), oxygen (O₂), or carbon tetrafluoride (CF₄) for removing residual polymers resulting from the etching process, wherein the etching process and the in-situ dry cleaning process are performed in a same reaction chamber continuously.

13. The method of claim 12, wherein the gas further comprises an inert gas or nitrogen (N₂).

14. The method of claim 13, wherein the inert gas is argon.

15. The method of claim 12, wherein the gas provides hydrogen radicals for replacing atoms of the residual polymers.

16. The method of claim 12, wherein the low-k layer is an OSG layer, a FSG layer, or an ULK (k<2.5) layer.

17. The method of claim 12, wherein the etching process is a multi-step etching process.

18. The method of claim 12, wherein the substrate further comprises an etch-stop layer positioned above the low-k layer.

19. The method of claim 18, wherein the etch-stop layer is a silicon carbide layer.

20. The method of claim 19, wherein the method further comprises a step of etching the etch-stop layer before performing the etching process on the low-k layer.

21. The method of claim 12, wherein the method further comprises performing a wet cleaning process after the in-situ dry cleaning process.
